(19) United States
(12) Patent Application Publication
(10) Pub. No.: US 2019/0341230 A1
(43) Pub. Date: Nov. 7, 2019

(54) CERAMIC LINER WITH INTEGRATED FARADAY SHIELDING

(71) Applicant: ASM NEXX, INC., Billerica, MA (US)

(72) Inventor: Daniel GOODMAN, Billerica, MA (US)

(21) Appl. No.: 16/400,332

(22) Filed: May 1, 2019

Related U.S. Application Data
(60) Provisional application No. 62/666,361, filed on May 3, 2018.

(51) Int. Cl. H01J 37/32; H01L 21/67

(52) U.S. Cl. CPC H01J 37/32477; H01J 37/32807; H01J 37/321; H01J 2237/334; H01L 21/67069; H01J 2237/24585; H01J 2237/0266; H01J 37/32467

(57) ABSTRACT

A plasma processing system for processing a semiconductor substrate, the system including a plasma processing chamber having a substrate support member configured for receiving a semiconductor substrate within the plasma processing chamber; a process gas delivery system configured to deliver process gas to the plasma processing chamber; a power source configured to energize process gas within the plasma processing chamber to create plasma; and a component positioned between the power source and the substrate support member, the component including a ceramic liner and a Faraday shield in contact with a surface of the ceramic liner.

### CROSS REFERENCE TO RELATED APPLICATION

This application claims priority from U.S. Provisional Application Ser. No. 62/666,361, filed May 3, 2018, the entire disclosure of which is hereby incorporated by reference.

### BACKGROUND OF THE INVENTION

This disclosure relates to semiconductor manufacturing. There are many process steps executed to fabricate integrated circuits. Various patterning, deposition, and cleaning steps are executed to fabricate and create packages for integrated circuits. Such steps can include dry cleaning operations in which plasma is used to clean or remove materials from a substrate. One constant challenge with fabrication of semiconductors is preventing contamination of devices and substrates.

Techniques herein provide particle reduction systems and methods. This includes particle reduction in plasma cleaning systems such as an inductively coupled plasma (ICP) sputter clean etch chamber of a physical vapor deposition (PVD) tool. During etch processing, various metal and polymer species are deposited on a ceramic liner. In high volume production, such liners increased in temperature as a result of radio frequency (RF) power coupling and plasma processes. Such heating of the ceramic liner is problematic because particle spallation occurs due to thermal cycling of the liner.

An integrated liner with Faraday shield herein can be held at a constant temperature, thereby preventing such particle spallation. Conventional systems have used Faraday shields and ceramic liners in ICP etch chambers, with the Faraday shields used to modify RF fields in the etch chamber. Also, Faraday shields and ceramic liners are purposefully separated, some with cooling for the Faraday shield.

### SUMMARY OF THE INVENTION

In contrast, techniques herein include a liner with integrated Faraday shield. The Faraday shield is used to heat the ceramic liner to prevent particle production in a corresponding etch chamber. Such heating can include pre-heating prior to substrate processing.

One embodiment includes a plasma processing system for processing a semiconductor substrate. This system includes a plasma processing chamber having a substrate support member configured for receiving a semiconductor substrate within the plasma processing chamber. A process gas delivery system is configured to deliver process gas to the plasma processing chamber. A power source is configured to energize process gas within the plasma processing chamber to create plasma. A component is positioned between the power source and the substrate support member, the component comprising a ceramic liner and a Faraday shield in contact with a surface of the ceramic liner. The plasma processing gas flow and pumping may be configured to maintain a pressure less than atmospheric pressure.

Of course, the order of discussion of the different steps as described herein has been presented for clarity's sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

Note that this summary section does not specify every embodiment and/or incrementally novel aspect of the present disclosure or claimed invention. Instead, this summary provides preliminary discussion of different embodiments and corresponding points of novelty over conventional techniques. For additional details and/or possible perspectives of the invention and embodiments, the reader is directed to the Detailed Description section and corresponding figures of the present disclosure as further discussed below, and the accompanying claims.

Systems and methods herein include a component comprising an integrated liner with a Faraday shield. With such integration, a ceramic liner can be held at a constant temperature to prevent particle spallation. The Faraday shield is used to heat the ceramic liner to prevent particle production in a corresponding etch chamber. Such heating can include pre-heating prior to substrate processing to avoid thermal cycling of the liner in the presence of a substrate.

The liner with integrated Faraday shield herein can increase liner lifetime before needing to be cleaned because of improved adhesion of sputtered material on the liner. Etch uniformity can be improved by a suitable selection of Faraday shielding pattern.

In one example method, there are various process steps available to be used in various sequences for particle reduction with liners herein. The shield can be cleaned prior to use and/or at intervals as part of routine maintenance. Bead blasting can be used for such cleaning. The liner can be installed or positioned with a Faraday pattern facing a ceramic window of an etch chamber. Thus, a ceramic surface of the liner is positioned to face a substrate when positioned in the etch chamber, while an opposing side having an integrated Faraday shield faces a ceramic window of a corresponding etch chamber. The etch chamber can be pumped to vacuum or to a particular operating pressure.

An ICP or other power source is turned on to a predetermined power level (such as a power level used for wafer processing or higher) to heat the ceramic liner via eddy currents in the Faraday shield. Different shielding patterns can result in different heating. The liner can be heated until reaching an equilibrium temperature or operating temperature during etch operations. The liner or system can include a temperature sensor to measure and indicate when the liner has reached a desired temperature. ICP power can be turned off for a period of time, such as to place a given substrate in the plasma etch chamber. A given etch process can then be executed with the liner already at an equilibrium temperature for that etch process. A temperature of the liner can be measured continuously or periodically, such as with a fiber optic temperature sensor. ICP power can be turned on at various times to maintain the liner at a particular temperature or temperature range.

With such techniques, metal and polymer that is sputtered onto a liner during etch processing can be deposited over a range of liner temperatures. Films from such metal and polymer sputtering typically have a higher coefficient of thermal expansion (CTE) than the liner. For example aluminum has a CTE of 21-24×10\hat{ }-6 (m/m-K) compared to a quartz liner CTE of 8-14×10\hat{ }6 (m/m-K). As the liner heats up during processing, the CTE mismatch can contribute to spallation of the film, which causes particles to collect on a wafer. If the liner is already at equilibrium temperature prior to etch, however, then the sputtered film will not experience the thermal ramp, and will remain better adhered to the liner. A wafer can be periodically used to sputter etch onto the liner to increase adhesion through a pasting process.

### BRIEF DESCRIPTION OF THE DRAWINGS

The invention will be described with reference to the accompanying drawings, in which:

FIG. 1 schematically illustrates, in sectional view, a conventional etch chamber;

FIG. 2 is a plot showing temperatures of a separated Faraday shield and a quartz liner with respect to time for a particular etch chamber and process parameters

FIG. 3A schematically shows, in perspective view, a component comprising a ceramic liner incorporating a Faraday shield, in accordance with an embodiment of the present invention;

FIG. 3B schematically shows a sectional view of the component of FIG. 3A;

FIG. 4 schematically illustrates, in sectional view, an etch chamber having a liner with an integrated Faraday shield, in accordance with another embodiment of the present invention; and

FIG. 5 schematically shows, in sectional view, an etch chamber with both an integrated liner-shield and a second Faraday shield, in accordance with a further embodiment of the present invention.

### DETAILED DESCRIPTION OF EMBODIMENTS

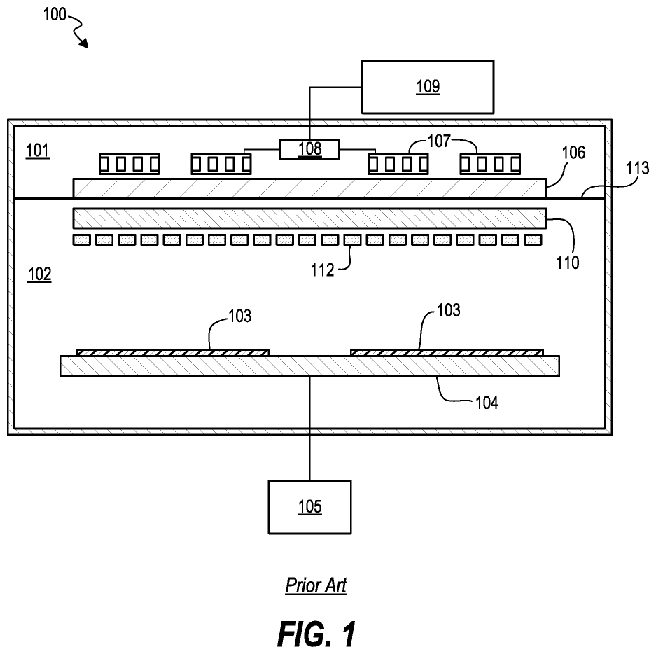

Now referring to the drawings, FIG. 1 illustrates a conventional plasma processing chamber 100 (also known as an “etch chamber”), which includes chuck support member 104, semiconductor substrates in the form of wafers 103, RF high frequency bias generator 105, a power source including RF low frequency ICP generator 109, matching network 108 and ICP coils 107, a first sub-chamber 101 (which can be at atmospheric pressure/atmosphere, and so is hereafter denoted “atmosphere chamber”), a second sub-chamber 102 (which may be subjected to a vacuum and hence is hereafter denoted “vacuum chamber”), ceramic liner 110 and conventional Faraday shield 112. The plasma processing chamber 100 is divided into the first and second sub-chambers 101, 102 by a partition separating vacuum from atmosphere, the partition including both a metal wall 113 and a ceramic window 106 located in the metal wall 113 and positioned between the power source and the ceramic liner 110. The Faraday shield 112 is located between the liner 110 and the chuck support member 104, and separated from the liner 110.

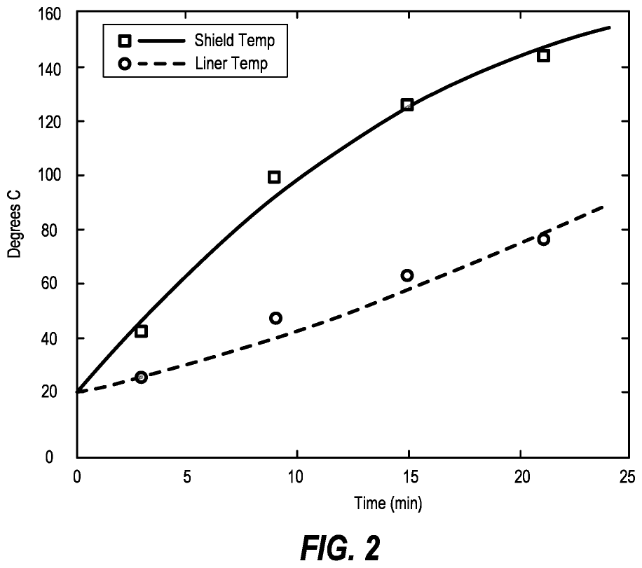

FIG. 2 is a plot showing temperatures of a separated Faraday shield and a quartz liner with respect to time for a particular etch chamber and process parameters. Process parameters for this example include using a low frequency RF generator delivering 450 W at 2 MHZ to the ICP coil, with a high frequency RF bias generator delivering 600 W, and introducing argon gas at 1 mTorr into the chamber. In this example, 149 W of RF power was deposited into the shield while 50 W of plasma power was deposited into the shield. In this example, shield heating reached an equilibrium temperature of 156 C in 14 minutes, while the liner reaching an equilibrium temperature of 85 C in 35 minutes. RF current in the ICP coil induces eddy currents in the Faraday shield causing the Faraday shield to heat. A cooling mechanism for the Faraday shield can be from radiation. Some of this radiation is directed to the liner, which causes the liner to slowly heat, increasing the liner temperature. Of course, heating times can vary depending on a given etch chamber used, power used, shield pattern, material properties, et cetera. Using higher ICP power the liner can heat up at a greater rate. During etch processing, the liner can heat up significantly, which can cause spallation of films deposited at low temperature.

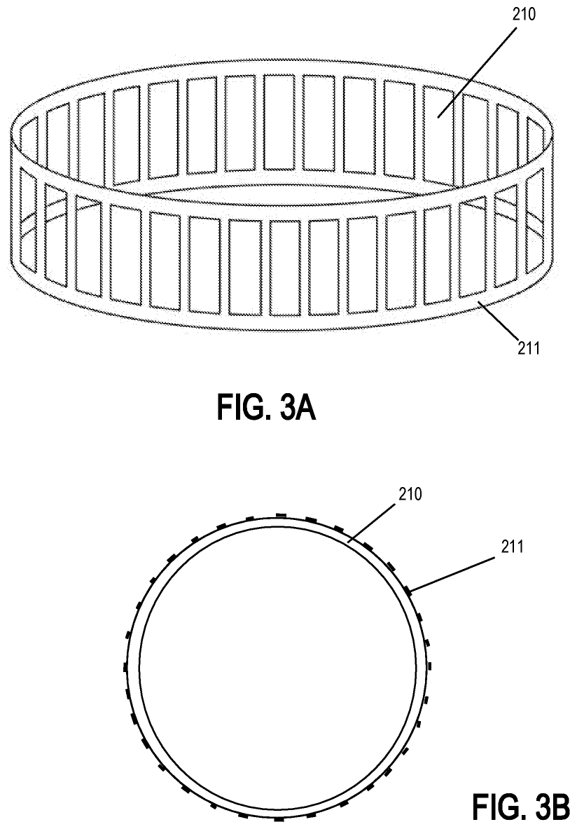

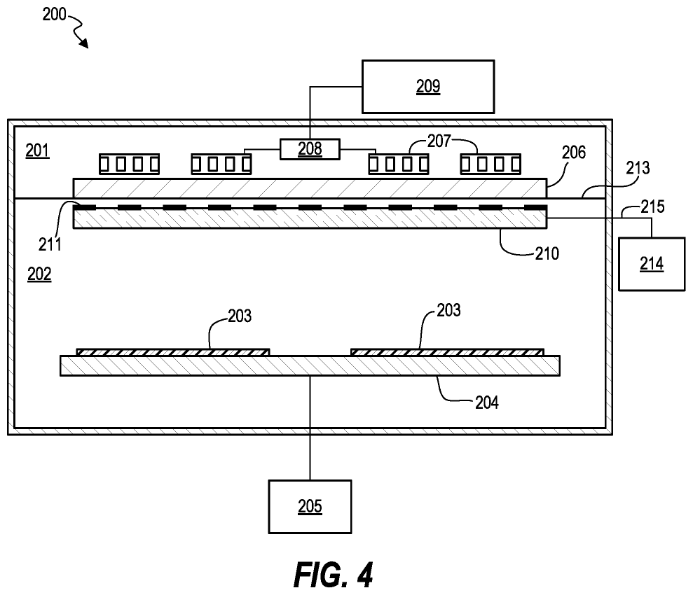

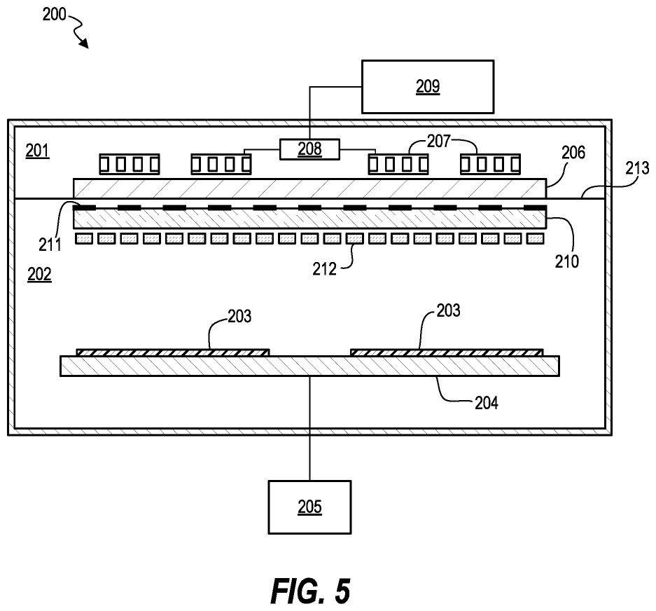

Components in accordance with embodiments of the present invention include, for example, a Faraday shield adhered to or integrated with a ceramic liner. This Faraday shield can be patterned from stainless steel or other metal. FIGS. 3A and 3B schematically show one example embodiment of such a component having a Faraday shield 211 in contact with a ceramic liner 210. In this specific embodiment, the liner 210 is formed from a sheet of quartz material formed into a tube or cylinder of substantially circular section, the sheet here having a thickness of about 3mm. Such a liner 210 is optically transparent or translucent, and is most clearly identifiable in the section view of FIG. 3B. The Faraday shield 211 in this embodiment is formed from strips of metal adhered to, or formed on, an exterior surface of the liner 210. Other liners (such as those shown in FIGS. 4 and 5) can be formed as substantially circular disks, depending on the configuration of power coupling of a given plasma processing system (top power or side power). Forming stainless steel strips on a single surface of a sheet-like liner permits cleaning of the other surface of the liner using bead blasting or other methods without affecting the metal patterning. Temperature sensors (see FIG. 4 for example) can be integrated with a given shielding pattern.

Such an integration enables beneficial thermal coupling for faster heating of the liner. By way of a non-limiting example, using 800 W of ICP power applied to the system, approximately 200 W was absorbed in the liner. The liner herein reaches the equilibrium temperature of 80 degrees C. in nine minutes instead of 35 minutes. Thus, by using high power ICP, the integrated liner can quickly reach equilibrium temperature.

FIG. 4 illustrates a plasma processing/etch chamber 200 which is generally similar to that shown in FIG. 1, though in this case, and in accordance with an embodiment of the present invention, with a component comprising a ceramic liner 210 having an integrated Faraday shield 211. Similarly to the chamber 100 shown in FIG. 1, plasma processing chamber 200 includes chuck support member 204, wafers 203, RF high frequency bias generator 205, a power source including RF low frequency ICP generator 209, matching network 208 and ICP coils 207, atmosphere chamber 201 and a vacuum chamber 202. The plasma processing chamber 200 is divided into the atmosphere and vacuum chambers 201, 202 by a partition including both a metal wall 213 and a ceramic window 206 located in the metal wall 213 and positioned between the power source and the ceramic liner 210, the partition separating vacuum from atmosphere. The system 200 includes fiber optic temperature sensor 215 connected to in and thermometer readout unit 214. The component herein can, for example, be manufactured by adding metal patterning onto the ceramic liner 210 to form the Faraday shield 211. Ceramic liner materials can include quartz, alumina or other ceramics. Metal pattering material includes aluminum, copper, titanium, stainless steel or other metals. Methods to pattern the Faraday shield 211 onto the ceramic liner 210 include sputtering, painting, plasma spray, electrochemical deposition, attachment of patterned shields using adhesive or other methods. A metal patterning thickness deposited onto the liner can be in the range of 1-100 um, and more preferably in the range of 5-20 um. Fiber optic sensors 215 and thermometer 214 are available from a variety of vendors.

FIG. 5 shows a plasma processing/etch chamber 200 similar to that of FIG. 4, here having both an integrated liner-shield component 210 as well as a second Faraday shield 212. In this embodiment, wafer 203 can be made of a metal, a metal oxide or a polymer material. Selectable metals for wafer 203 include aluminum, titanium, stainless steel or other metals. Selectable metal oxides include silicon dioxide, silicon nitrite, silicon oxy-nitride or other oxides. Selectable polymers may include polyimide, benzocyclobutene or other polymers. An additional process step which can be combined with the use of the LIFS to improve particle performance in the etch chamber includes periodically sputter etching wafer 203 onto the integrated liner-shield component 210 to increase adhesion through a pasting process.

Other embodiments include a method of processing a substrate. An inductively-coupled plasma processing system configured to receive a substrate in a plasma processing chamber is provided. Prior to receiving the substrate within the plasma processing chamber, an inductively-coupled power supply is activated that heats a Faraday shield in contact with a ceramic liner which heats the ceramic liner. The ceramic liner is positioned within the plasma processing chamber. Subsequent to the ceramic liner reaching a predetermined temperature the substrate is introduced into the plasma processing chamber. This predetermined temperature can be an equilibrium temperature of corresponding plasma processing treatment for the substrate. The substrate is then processed using plasma energized from the plasma processing system. Methods can include monitoring a temperature of the ceramic liner and heating the ceramic liner via the Faraday shield when the temperature of the ceramic liner is less than a predetermined threshold temperature.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

1. A plasma processing system for processing a semiconductor substrate, the system comprising:
a plasma processing chamber having a substrate support member configured for receiving a semiconductor substrate within the plasma processing chamber;
a process gas delivery system configured to deliver process gas to the plasma processing chamber;
a power source configured to energize process gas within the plasma processing chamber to create plasma;
a component positioned between the power source and the substrate support member, the component comprising a ceramic liner and a Faraday shield in contact with a surface of the ceramic liner.

2. The system of claim 1, wherein the Faraday shield is adhered to the surface of the ceramic liner.

3. The system of claim 1, wherein the Faraday shield is formed on the ceramic liner using a forming technique selected from the group consisting of sputtering, painting, plasma spray and electrochemical deposition.

4. The system of claim 3, wherein the Faraday shield is formed having a thickness in the range of 1-100 microns.

5. The system of claim 3, wherein the Faraday shield is formed having a thickness in the range of 5-20 microns.

6. The system of claim 1, wherein the component is removable from the plasma processing chamber.

7. The system of claim 1, wherein the Faraday shield includes a pattern of metal formed on the ceramic liner.

8. The system of claim 1, wherein the Faraday shield is formed integrally with the ceramic liner.

9. The system of claim 1, wherein the plasma processing chamber is divided into first and second sub-chambers by a partition, and wherein the partition includes a ceramic window positioned between the power source and the ceramic liner.

10. The system of claim 9, wherein the Faraday shield is formed on a surface of the ceramic liner, to face the ceramic window in use.

11. The system of claim 1, further comprising a second Faraday shield positioned within the plasma processing system at a predetermined distance from the ceramic liner.

12. The system of claim 1, wherein the power source is an inductively-coupled plasma power source.

13. The system of claim 1, further comprising a temperature sensor mounted on the ceramic liner and connected to a controller that controls the power source.

14. A component for positioning within a plasma processing chamber of an inductively-coupled plasma processing system, the component comprising:
a ceramic liner, and a Faraday shield formed in contact with a surface of the ceramic liner.

15. The component of claim 14, being configured to be positioned between a ceramic window of the inductively-coupled plasma processing system and a substrate support member configured to hold a substrate within the plasma processing chamber.

16. The component of claim 14, wherein the Faraday shield is adhered to the ceramic liner.

17. The component of claim 14, wherein the Faraday shield is formed on the ceramic liner using a forming technique selected from the group consisting of sputtering, painting, plasma spray and electrochemical deposition.

18. The component of claim 14, wherein the Faraday shield includes a pattern of metal formed on the ceramic liner.

19. The component of claim 14, wherein the Faraday shield is formed integrally with the ceramic liner.

20. A plasma processing system for processing a semiconductor substrate, the plasma processing system comprising the component of claim 14.
